(19) United States
(12) Patent Application Publication
(10) Pub. No.: US 2005/0185486 A9
(43) Pub. Date: Aug. 25, 2005

(54) Ferroelectric memory devices including protection adhesion layers and methods of forming the same

(76) Inventors: Kyu-Mann Lee, Gyeonggi-do (KR); Kun-sang Park, Gyeonggi-do (KR); Sang-don Nam, Seoul (KR)

Correspondence Address: Robert N. Crouse;Myers Bigel Sibley & Sajovec, Post Office Box 37428, Raleigh, NC, 27627, US

(21) Appl. No.: 10/721,480

(22) Filed: Nov. 25, 2003

(30) Foreign Application Priority Data
Nov. 26, 2002 (KR) 2002-73906
Jul. 7, 2003 (KR) 2003-45784

(51) Int. Cl. G11C 7/00

(52) U.S. Cl. 365/202

(57) ABSTRACT

A ferroelectric memory device includes an interlayer dielectric layer and a a protection adhesion layer formed thereon. A buried contact extends through the protection adhesion layer and the interlayer dielectric layer. A lower electrode is on a portion of the protection adhesion layer that is adjacent to the buried contact and on the buried contact. A ferroelectric layer covers the lower electrode and the protection adhesion layer. An upper electrode overlaps the lower electrode and covers the ferroelectric layer. Related methods are also disclosed.

### CLAIM FOR PRIORITY

This application claims priority to Korean Patent Application No. 2002-73906, filed in the Korean Intellectual Property Office on Nov. 26, 2003, and to Korean Patent Application No. 2003-45784, filed in the Korean Intellectual Property Office on Jul. 7, 2003, the entire disclosures of which are incorporated herein by reference.

### FIELD OF THE INVENTION

The present invention relates generally to memory devices and, more specifically, to ferroelectric memory devices and methods for forming the same.

### BACKGROUND

A ferroelectric memory device uses polarization of a ferroelectric layer. Some ferroelectric memory devices include one access transistor and one cell capacitor using a ferroelectric layer as a dielectric layer. FIG. 1 is a schematic cross-sectional view of a ferroelectric memory device according to a conventional technology. Referring to FIG. 1, gate electrodes (not shown) are formed on a substrate 1. Source/drain regions (not shown) are formed in the substrate 1 between gate electrodes. An interlayer dielectric layer 3 is formed to cover source/drain regions and gate electrodes. The interlayer dielectric layer 3 can be formed of a material such as silicon oxide layer.

Referring still to FIG. 1, a contact hole is formed by patterning the interlayer dielectric layer 3 and exposing the drain region of the substrate 1. The contact hole is filled with a conductive layer to form a buried contact 5. A lower electrode layer is formed on an entire surface of the substrate 1 that includes the buried contact 5 and is patterned to form a lower electrode 7. A ferroelectric layer 9 is formed to cover the lower electrode 7. An annealing process is performed to crystallize the ferroelectric layer 9. An upper electrode layer is formed on the ferroelectric layer 9 and patterned to form an upper electrode 11.

However, a portion of the lower electrode 7 may lift off the interlayer dielectric layer 3 during formation of the ferroelectric (as pointed out with “E” in FIG. 1). Additionally, during the annealing process for crystallizing the ferroelectric layer 9 to promote a perovskite structure, the ferroelectric layer 9 may react with portions of the interlayer dielectric layer 3 that are not covered by the lower electrode 7, thereby forming a pyrochlore phase in the ferroelectric layer 9. This may results in a volumetric expansion that forms a void (V) in a subsequent process.

A ferroelectric memory device and a method of forming the same disclosed in Korean Patent granted No. 10-0195262 are discussed herein with reference to FIG. 2. Referring to FIG. 2, a protection adhesion layer 6, such as a titanium oxide layer, is formed on an entire surface of a substrate 1 including a buried contact 5. The protection adhesion layer 6 is patterned to expose the buried contact 5. Subsequently, a lower electrode 7 is formed to cover a portion of the protection adhesion layer 6 and the exposed portion of the buried contact 5. A ferroelectric layer 9 and an upper electrode 11 are formed thereon. However, according to this structure and method, the protection adhesion layer 6 is patterned after forming the buried contact 5. Therefore, if a misalignment occurs during the patterning process, the lower electrode 7 may be in direct contact with the interlayer dielectric layer 3, which may result in the lifting phenomenon discussed above in reference to FIG. 1.

### SUMMARY

Embodiments according to the invention can provide ferroelectric memory devices with protection adhesion layers and methods of forming the same. Pursuant to some embodiments according to the invention, a ferroelectric memory device includes an interlayer dielectric layer and a a protection adhesion layer formed thereon. A buried contact extends through the protection adhesion layer and the interlayer dielectric layer. A lower electrode is on a portion of the protection adhesion layer that is adjacent to the buried contact and on the buried contact. A ferroelectric layer covers the lower electrode and the protection adhesion layer. An upper electrode overlaps the lower electrode and covers the ferroelectric layer.

In other embodiments according to the invention, an interlayer dielectric layer and a protection adhesion layer are formed, respectively, on a substrate. A contact hole is formed through the interlayer dielectric layer and the protection adhesion layer to expose the substrate. A buried contact is formed in the contact hole that extends through the interlayer dielectric layer and the protection adhesion layer. A lower electrode is formed on the buried contact and on a portion of the protection adhesion layer adjacent to the buried contact to leave a remaining portion of the protection adhesion layer exposed. A ferroelectric layer is formed on the lower electrode and on the protection adhesion layer. An upper electrode is formed on the ferroelectric layer and overlapping the lower electrode.

In some embodiments according to the invention, the buried contact includes an upper buried contact portion comprising a barrier pattern that extends from the lower electrode through the protection adhesion layer and a lower buried contact portion that extends from the barrier pattern through the interlayer dielectric layer.

### BRIEF DESCRIPTION OF THE DRAWINGS

FIG. 1 is a schematic cross-sectional view of a ferroelectric memory device according to the prior art.

FIG. 2 is a schematic cross-sectional view of a ferroelectric memory device according to the prior art.

FIG. 3 is a schematic cross-sectional view of a ferroelectric memory device according to some embodiments of the invention.

FIGS. 4A through 4D are cross-sectional views illustrating methods of sequentially forming the ferroelectric memory device of FIG. 3.

FIG. 5 is a schematic cross-sectional view of a ferroelectric memory device according to some embodiments of the invention.

FIG. 6 is a schematic cross-sectional view of a ferroelectric memory device according to some embodiments of the invention.

FIG. 7 is a schematic cross-sectional view of a ferroelectric memory according to some embodiments of the invention.

FIGS. 8A through 8D are cross-sectional views illustrating methods of forming the ferroelectric memory device of FIG. 7.

FIG. 9 is a schematic cross-sectional view of a ferroelectric memory device according to some embodiments of the invention.

FIG. 10 is a schematic cross-sectional view of a ferroelectric memory device according to some embodiments of the invention.

### DESCRIPTION OF EMBODIMENTS ACCORDING TO THE INVENTION

The invention will now be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art.

In the drawings, the thickness of layers and regions are exaggerated for clarity. It will be understood that when an element such as a layer, region or substrate is referred to as being “on” another element, it can be directly on the other element or intervening elements may also be present.

Furthermore, relative terms, such as “lower” and “upper”, may be used herein to describe one element's relationship to another elements as illustrated in the Figures. It will be understood that relative terms are intended to encompass different orientations of the device in addition to the orientation depicted in the Figures. For example, if the device in the Figures is turned over, elements described as being on the “lower” of other elements would then be oriented on “upper” of the other elements. The exemplary term “lower”, can therefore, encompasses both an orientation of lower and upper, depending of the particular orientation of the figure.

It will be understood that although the terms first and second are used herein to describe various regions, layers and/or sections, these regions, layers and/or sections should not be limited by these terms. These terms are only used to distinguish one region, layer or section from another region, layer or section. Thus, a first region, layer or section discussed below could be termed a second region, layer or section, and similarly, a second without departing from the teachings of the present invention. Like numbers refer to like elements throughout.

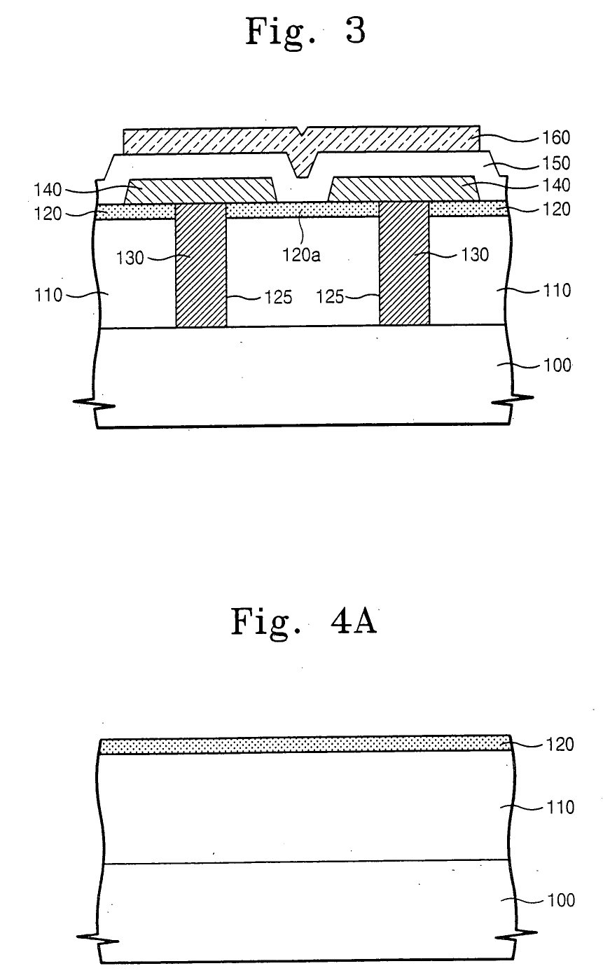

FIG. 3 is a schematic cross-sectional view of a ferroelectric memory device according to some embodiments of the invention. Referring to FIG. 3, a plurality of gate electrodes (not shown) are arranged on a substrate 100 (such as a substrate), and source/drain regions (not shown) are disposed in the substrate 100 between gate electrodes. A bit line (not shown) is formed to be in contact with the source region. An interlayer dielectric layer 110 and a protection adhesion layer 120 are sequentially formed to cover the plurality of gate electrodes and source/drain regions. In some embodiments according to the invention, the protection adhesion layer 120 is a titanium oxide (TiO₂) layer.

A contact hole 125 is formed through the interlayer dielectric layer 110 and the protection adhesion layer 120 to expose the drain region (not shown) of the substrate 100. A buried contact 130 fills the contact hole 125 and is electrically connected to the drain region (not shown). A lower electrode 140 is formed on the buried contact 130 and to partially cover the protection adhesion layer 120 adjacent to the buried contact 130. A ferroelectric layer 140 covers the lower electrode 150 and a portion of the protection adhesion layer 120 that is not covered by the lower electrode 140. An upper electrode 160 is formed to cover the ferroelectric layer 150 and to overlap the lower electrode 140, to provide a structure of a capacitor. In some embodiments according to the invention, the upper electrode 160 overlaps at least two of the lower electrodes 140.

In some embodiments according to the invention, the ferroelectric layer 150 may be formed of one or more of the following materials: PZT[Pb(Zr, Ti)O₃], PbTiO₃, SrTiO₃, BaTiO₃, PbLaTiO₃, (Pb, La) (Zr, Ti)O₃, BST[(Ba, Sr)TiO₃], Ba₄Ti₃O₁₂, SrBi₂Ta₂O₉ and Bi₄Ti₃O₁₂. Other materials/combinations can be used for the ferroelectric layer 150. In some embodiments according to the invention, the lower electrode 140 and the upper electrode 160 may be formed of one or more of the following materials: ruthenium (Ru), platinum (Pt), rhodium (Rh), osmium (Os), palladium (Pd), ruthenium oxide (RuOₓ), iridium oxide (IrOₓ), platinum oxide (PtOₓ), rhodium oxide (RhOₓ), osmium oxide (OsOₓ) and palladium oxide (PdOₓ). Other materials/combinations can be used for the lower electrode 140 and the upper electrode 160.

In some embodiments according to the invention, the protection adhesion layer 120 is formed of titanium oxide to promote good adhesion with the lower electrode 140. The protection adhesion layer 120 may also reduce the likelihood of a pyrochlore phase being induced in the ferroelectric layer 150. That is, the protection adhesion layer 120 can promote adhesion between the lower electrode 140 and the interlayer dielectric layer 110, and also can help suppress a reaction between the ferroelectric layer 150 and the interlayer dielectric layer 110 since the protection adhesion layer 120 separates the lower electrode 140 and the ferroelectric layer 150 from the interlayer dielectric layer 110. Suppressing the reaction may help prevent the formation of a void V (and lifting E) due to a reaction between the ferroelectric layer and the interlayer dielectric layer. In addition, the upper electrode 160 is formed to overlap two of the lower electrodes 140. Therefore, sufficient process margin can be obtained when a plate line is formed in a subsequent process.

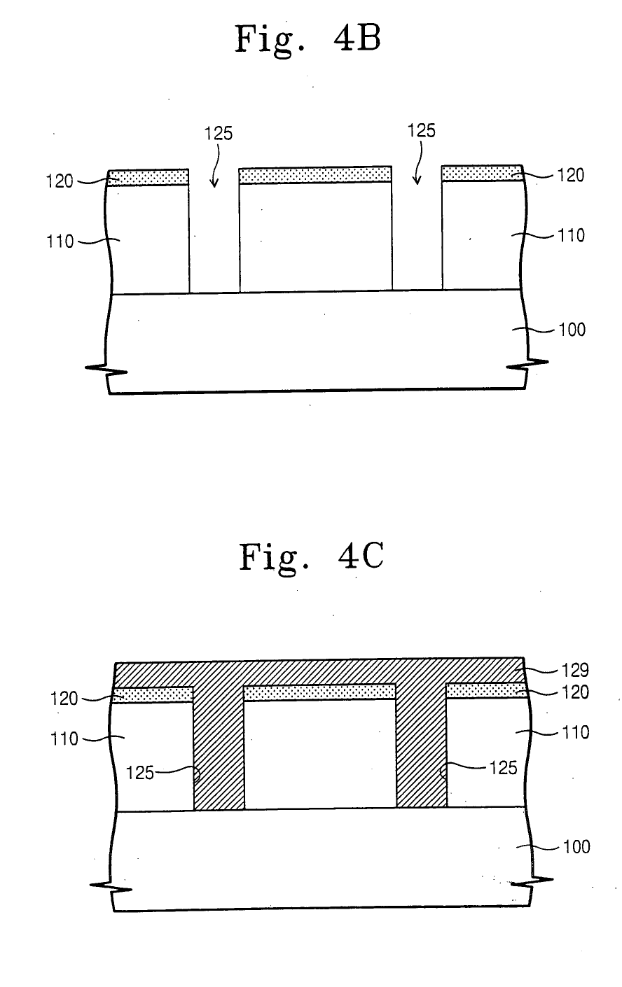

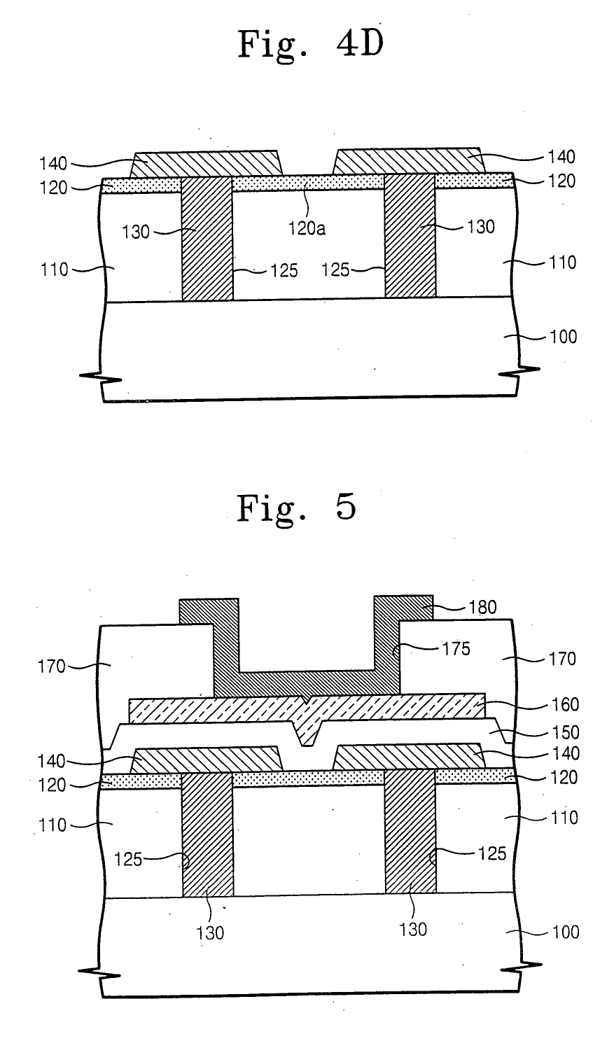

FIG. 4A through FIG. 4D are cross-sectional views showing methods of forming the ferroelectric memory device of FIG. 3 according to embodiments of the invention. Referring to FIG. 4A, a plurality of gate electrodes (not shown) are formed on a substrate 100, and source/drain regions (not shown) are formed on the substrate 100 between the gate electrodes. A bit line (not shown) is formed to contact the source region (not illustrated). An interlayer dielectric layer 110 is formed on an entire surface of the substrate 100 including the gate electrodes and the source/drain regions. In some embodiments according to the invention, the interlayer dielectric layer 110 is formed of one or more of the following materials: HSQ (Hydrogen Silsesquioxane), BPSG (Boron Phosphorus Silicate Glass), HDP (High density plasma) oxide, PETEOS (Plasma enhanced tetraethyl orthosilicate), USG (Undoped Silicate Glass), PSG (Phosphorus Silicate Glass), PE-SiH₄ and Al₂O₃ using one or more of the following processes: PECVD (plasma-enhanced chemical vapor deposition), LPCVD (Low-pressure chemical vapor deposition), ALD (Atomic layer deposition) and SOG (Spin on glass). A protection adhesion layer 120 is formed on the interlayer dielectric layer 110. In some embodiments according to the invention, the protection layer 120 is formed of TiO₂ by a CVD method.

Referring to FIG. 4B, the protection layer 120 and the interlayer dielectric layer 110 are sequentially patterned to form a contact hole 125 exposing the drain region (not shown). The protection adhesion layer 120 (formed, for example, of titanium oxide) may be etched using a mixture of carbonated fluoride gas (e.g., CHF₃ or CF₄) and chloride gas (e.g., Cl₂). The interlayer dielectric layer 110 may be etched using carbonated fluoride gas (e.g., CHF₃ or CF₄).

Referring to FIG. 4C, a conductive layer 129 is formed on an entire surface of the substrate 100 including in the contact hole 125 to fill the contact hole 125. In some embodiments according to the-invention, the conductive layer 129 is formed of one or more of the following materials: tungsten, aluminum, copper and polysilicon layer doped or undoped with impurities. Other materials mat be used.

Referring to FIG. 4D, a planarization process, such as Chemical Mechanical Polishing (CMP), is performed on the conductive layer 129 to expose the protection adhesion layer 120 and simultaneously to form a buried contact 130 from the conductive layer 129 in the contact hole 125. A lower electrode layer (not illustrated) is formed on an entire surface of the substrate 100, including on the buried contact 130, and patterned to form a lower electrode 140 that overlaps the buried contact 130 and covers part of the protection adhesion layer 120. In some embodiments according to the invention, the lower electrode 140 is formed from one or more of the following materials: ruthenium (Ru), platinum (Pt), rhodium (Rh), osmium (Os), palladium (Pd), ruthenium oxide (RuOₓ), iridium oxide (IrOₓ) and platinum oxide (PtOₓ), rhodium oxide (RhOₓ), osmium oxide (OsOₓ) and palladium oxide (PdOₓ). The lower electrode 140 is deposited on the protection adhesion layer 120. As discussed above, the protection adhesion layer 120 can promote adhesion between the lower electrode 140 and the interlayer dielectric layer 110.

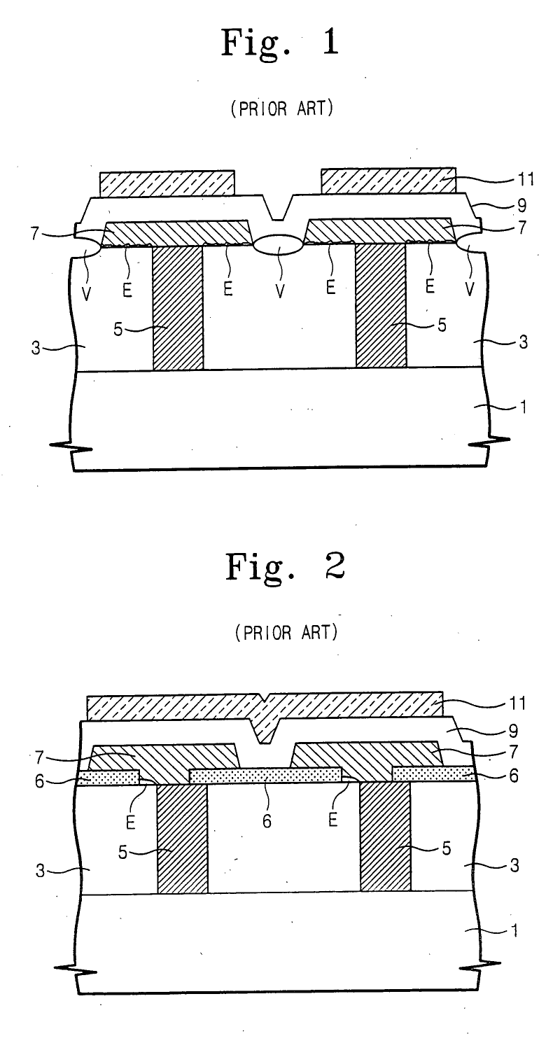

Referring again to FIG. 3, the ferroelectric layer 150 is formed to cover the lower electrode 140 and a portion of the protection adhesion layer 120 that is not covered by the lower electrode 140. In some embodiments according to the invention, the ferroelectric layer 150 may be formed of one or more of the following materials: PZT[Pb(Zr, Ti)O₃], PbTiO₃, SrTiO₃, BaTiO₃, PbLaTiO₃, (Pb, La) (Zr, Ti)O₃, BST[(Ba, Sr)TiO₃], Ba₄Ti₃O₁₂, SrBi₂Ta₂O₉ and Bi₄Ti₃O₁₂. In some embodiments according to the invention, the ferroelectric layer 150 is formed using one or more of sputtering, CVD, sol-gel and atomic layer deposition (ALD). An annealing process is performed to form a perovskite structure in the ferroelectric layer 150. A pyrochlore phase and a void (such as that shown in FIG. 1) may be reduced or avoided because the ferroelectric layer 150 does not contact with the interlayer dielectric layer 110.

An upper electrode layer (not illustrated) is formed on the ferroelectric layer 150 and patterned to form an upper electrode 160 that overlaps the lower electrode 140 and covers a portion of the ferroelectric layer 150. In some embodiments according to the invention, the upper electrode 160 is formed from one or more layers of the following materials: ruthenium (Ru), platinum (Pt), rhodium (Rh), osmium (Os), palladium (Pd), ruthenium oxide (RuOₓ), iridium oxide (IrOₓ) and platinum oxide (PtOₓ), rhodium oxide (RhOₓ), osmium oxide (OsOₓ) and palladium oxide (PdOₓ). Preferably, as shown in FIG. 3, the upper electrode 160 is formed to overlap at least two lower electrodes 140. Therefore, a process margin can be sufficiently obtained when a groove is formed for a plate line in a subsequent process.

FIG. 5 is a schematic cross-sectional view of a ferroelectric memory device according to some embodiments of the invention. Referring to FIG. 5, an upper interlayer dielectric layer 170 is formed on the structure shown in FIG. 3. The upper interlayer dielectric layer 170 may be formed of the same material as the interlayer dielectric layer 110. The upper interlayer dielectric layer 170 is patterned to form a groove that exposes the upper electrode 160. In some embodiments according to the invention, the upper electrode 160 is used as an etch stop layer when etching the upper interlayer dielectric layer 170. As shown in FIG. 5, a conductive material layer is conformally deposited along a profile of the groove 175 and patterned to form a plate line 180 as shown in FIG. 5. Since the upper electrode 160 overlaps at least two of the lower electrodes 140, the process margin for forming the groove 175 for the plate line 180 can be obtained sufficient.

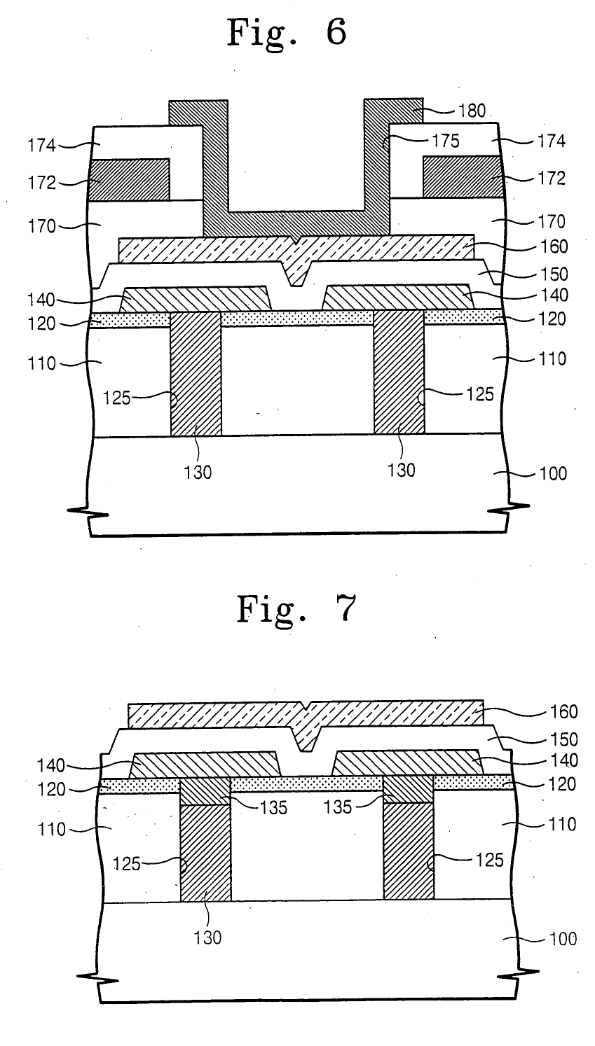

FIG. 6 is a schematic cross-sectional view of a ferroelectric memory device according to some embodiments of the invention. Referring to FIG. 6, an upper interlayer dielectric layer 170 is formed on the structure shown in FIG. 3. After forming a strip line 172 on the upper interlayer dielectric layer 170 (for an interconnection), an upper inter-metal dielectric layer 174 is formed to cover the strip line 172. The upper inter-metal dielectric layer 174 and the upper interlayer dielectric layer 170 are sequentially patterned to form a groove 175 exposing the upper electrode 160 and to form a plate line 180 electrically connecting to the upper electrode 160 through the groove 175. In some embodiments according to the invention, the strip line 172 and the plate line 180 are formed form one or more of the following materials: aluminum (Al), copper (Cu), tungsten (W), ruthenium (Ru), platinum (Pt), rhodium (Rh), osmium (Os), palladium (Pd), cobalt (Co), nickel (Ni), titanium (Ti), tantalum (Ta) titanium nitride layer (TiN) and tantalum nitride layer (TaN).

FIG. 7 is a schematic cross-sectional view of a ferroelectric memory according to another embodiment of the present invention. Referring to FIG. 7, a barrier pattern 135 is interposed between a lower electrode 140,and a buried contact 130 in a contact hole 125. The barrier pattern 135 can be formed from a single layer or from multiple layers of one or more of the following materials: TiN, TiAlN, TiSiₓ, TiSiN, TaSiN and TaAlN. The barrier pattern 135 can reduce or prevent oxidation of the buried contact 130 by reducing or blocking the penetration of oxygen and hydrogen. Additionally, the barrier pattern 135 may promote good adhesion with the lower electrode 140.

Although not illustrated, a titanium silicide layer (TiSiₓ) may be formed between the barrier pattern 135 and the buried contact 130 to provide an “ohmic” contact therebetween. As used herein, the term “ohmic” refers to configurations where an impedance between two elements is substantially given by the relationship of Impedance=V/I, where V is a voltage across the two elements and 1 is the current therebetween, at substantially all frequencies (i.e., the impedance between ohmically coupled elements is substantially the same at all frequencies.

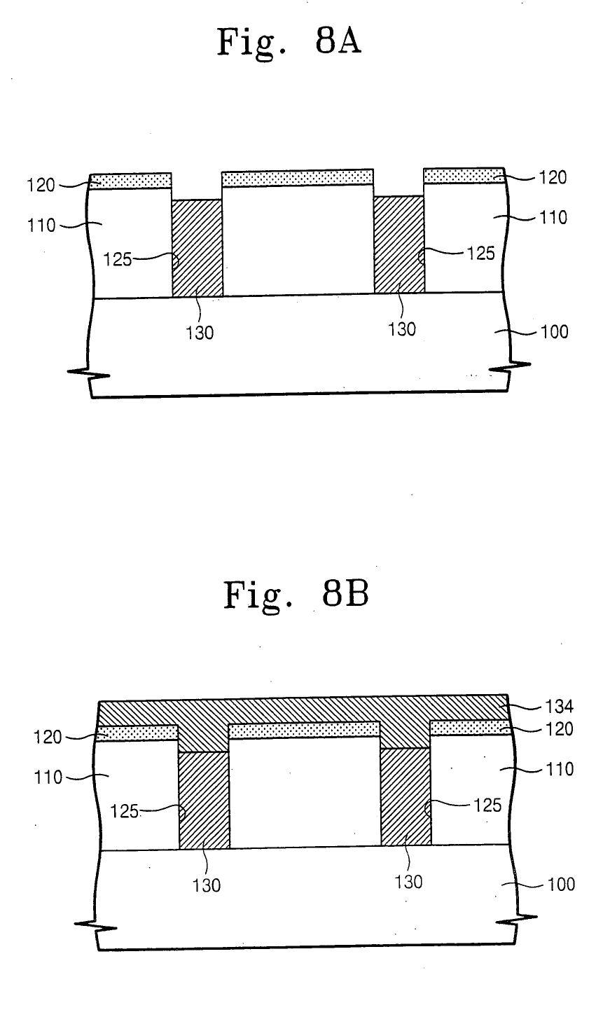

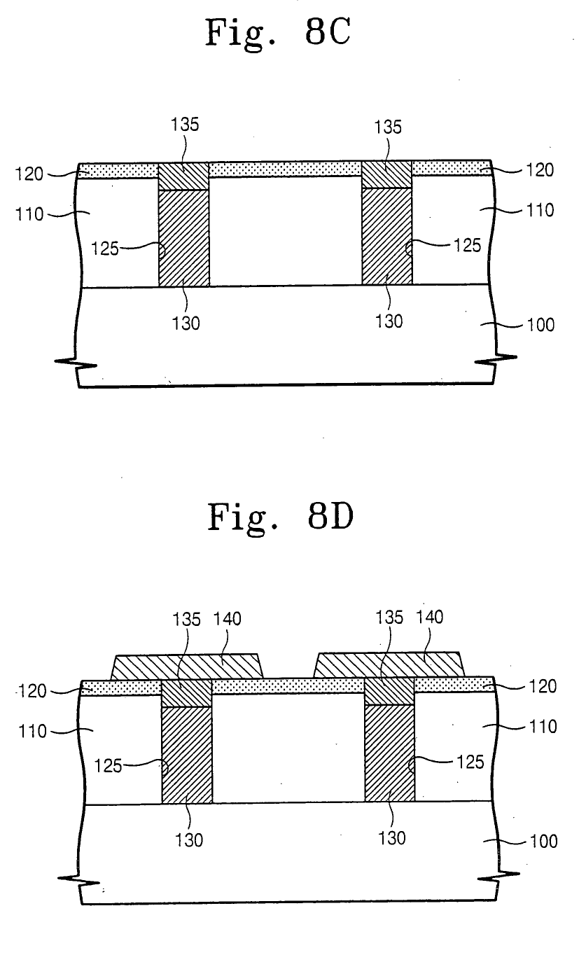

FIGS. 8A through 8D are cross-sectional views illustrating methods of forming ferroelectric memory devices according to embodiments of the invention. Referring to FIG. 8A, a planarization process (such as CMP) is performed, on the structure shown in FIG. 4C, with respect to a conductive layer 129 to expose a protection adhesion layer 120 and to form a buried contact (130 in FIG. 4D) of the conductive layer 129 in the contact hole 125. An upper part of the buried contact (130 in FIG. 4D) is recessed using an etch-back process to form the buried contact 130 below an opening of the contact hole 125. The etch-back process is performed using a difference in the etch rates of the protection adhesion layer 120 and the buried contact 130. The protection adhesion layer 120 is etched to a lesser extent while the upper part of the buried contact 130 is recessed.

Referring to FIG. 8B, a barrier layer 134 is formed on an entire surface of the substrate 100 having the buried contact 130, thereby filling the portion below the opening with the buried contact 130. In some embodiments according to the invention, the barrier layer 134 is formed from one or more of the following materials: TiN, TiAlN, TiSiₓ, TiSiN, TaSiN and TaAlN using at least one method selected from the group consisting of sputtering, CVD, sol-gel and atomic layer deposition (ALD).

Referring to FIG. 8C, a planarization process, such as CMP, is performed with respect to the barrier layer 134 to expose the protection adhesion layer 120 and to form a barrier pattern 135 that fills the upper part of the contact hole 125. Referring to FIG. 8D, a lower electrode layer (not illustrated) is formed on the barrier pattern 135 and on the protection adhesion layer 120, and is patterned to form a lower electrode 140. The lower electrode layer (not illustrated) is deposited on the barrier pattern 135 and the protection adhesion layer 120 without the lifting discussed above in reference to E shown in FIGS. 1 and 2.

Subsequently, a ferroelectric layer 150 is conformally deposited on the substrate having the lower electrode 140. An annealing process is performed to form a perovskite structure in the ferroelectric layer 150. Since the ferroelectric layer 150 does not directly contact with the interlayer dielectric layer 110 and the barrier layer 135, the formation of a pyrochlore phase and the formation of voids, such as V shown in FIG. 1, may be reduced or avoided. Additionally, since the barrier layer 135 is not exposed when the ferroelectric layer 150 is formed or when the annealing process using oxygen is performed, the inner stress of the barrier layer 135 can be reduced to avoid lifting of the lower electrode 130.

An upper electrode (not illustrated) is stacked on the ferroelectric layer 150 and patterned to form an upper electrode 160 overlapped with the lower electrode 140 and covering a part of the ferroelectric layer 150. Preferably, as shown in FIG. 5, the upper electrode is formed to overlap with at least two lower electrodes 140. Therefore, a process margin can be sufficiently obtained when a groove is formed for a plate line in a subsequent process.

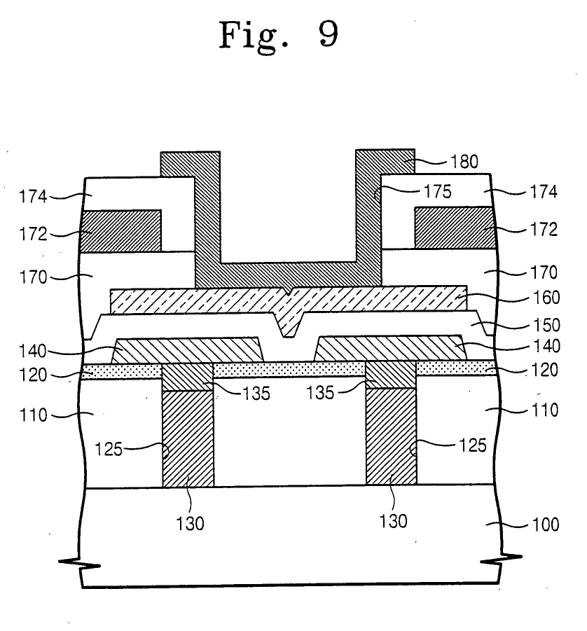

FIG. 9 is a schematic cross-sectional view of a ferroelectric memory device according to some embodiments of the invention. Referring to FIG. 9, an upper interlayer dielectric layer 170 is formed on the structure shown in FIG. 7. The upper interlayer dielectric layer 170 may be formed of the same material as the interlayer dielectric layer 110 by using the same method. The upper interlayer dielectric layer 170 is patterned to form a groove 175 exposing the upper electrode 160. In some embodiments according to the invention, the upper electrode 160 is used as an etch stop layer. A conductive material layer is conformally deposited on a profile of the groove 175 and patterned to form a plate line 180. Since the upper electrode 160 overlaps at least two lower electrodes 140, a process margin can be sufficiently obtained when the groove 175 is formed.

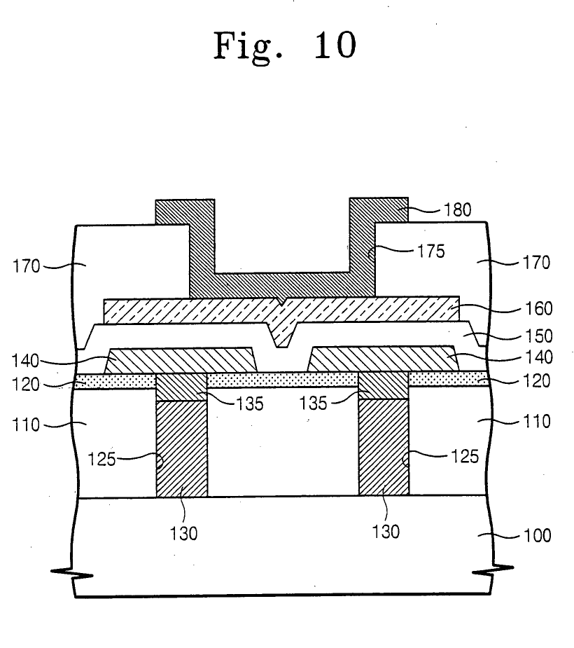

FIG. 10 is a schematic cross-sectional view of a ferroelectric memory device according to some embodiments of the invention. Referring to FIG. 10, an upper interlayer dielectric layer 170 is formed on the structure shown in FIG. 3. After forming a string line on the upper interlayer dielectric layer 170 (for interconnection), an upper inter-metal dielectric layer 174 is formed to cover the strip line 172. The upper inter-metal dielectric layer 174 and the upper interlayer dielectric layer 170 are sequentially patterned to form a groove 175 exposing the upper electrode 160 and to form a plate line 180 electrically connecting to the upper electrode 160 through the groove 175.

According to embodiments of the invention, a protection adhesion layer separates a lower electrode and a ferroelectric layer from a lower interlayer dielectric layer, so that the formation of voids and lifting (due to a reaction between an interlayer dielectric layer and a lower electrode and between the interlayer dielectric layer and the ferroelectric layer) can be reduced or prevented. A barrier layer can prevent oxidation of a buried contact since the barrier layer may not be exposed when the ferroelectric layer is formed, thereby inner stress of the barrier layer can be minimized to prevent lifting of a lower electrode. A ferroelectric layer does not directly contact an interlayer dielectric layer and a barrier layer, so that a pyrochlore phase in the ferroelectric layer may be avoided to improve reliability of a ferroelectric memory device. Additionally, since an upper electrode is overlapped with at least two lower electrodes, a process margin is sufficiently obtained when a groove is formed for a plate line.

While the invention has been particularly shown and described with reference to the embodiments herein, it will be understood by those of ordinary skill in the art that various changes in form and details may be made therein without departing from the spirit and scope of the invention as defined by the following claims.

1. A ferroelectric memory device comprising:
an interlayer dielectric layer;
a protection adhesion layer on the interlayer dielectric layer;
a buried contact extending through the protection adhesion layer and the interlayer dielectric layer;
a lower electrode on a portion of the protection adhesion layer adjacent to the buried contact and on the buried contact;
a ferroelectric layer covering the lower electrode and the protection adhesion layer; and
an upper electrode overlapping with the lower electrode and covering the ferroelectric layer.

2. A ferroelectric memory device according to claim 1 wherein the buried contact comprises:
an upper buried contact portion comprising a barrier pattern extending from the lower electrode through the protection adhesion layer; and
a lower buried contact portion extending from the barrier pattern through the interlayer dielectric layer.

3. A ferroelectric memory device according to claim 1 wherein the protection adhesion layer comprises titanium oxide layer (TiO₂).

4. A ferroelectric memory device according to claim 2 wherein the barrier pattern is selected from the group consisting of TiN, TiAlN, TiSiₓ, TiSiN, TaSiN and TaAlN.

5. A ferroelectric memory device according to claim 1 wherein the ferroelectric layer is selected from the group consisting of PZT[Pb(Zr, Ti)O₃], PbTiO₃, SrTiO₃, BaTiO₃, PbLaTiO₃, (Pb, La) (Zr, Ti)O₃, BST[(Ba, Sr)TiO₃], Ba₄Ti₃O₁₂, SrBi₂Ta₂O₉ and Bi₄Ti₃O₁₂.

6. A ferroelectric memory device according to claim 1 wherein the lower electrode and the upper electrode are selected from the group consisting of ruthenium (Ru), platinum (Pt), rhodium (Rh), osmium (Os), palladium (Pd), ruthenium oxide (RuOₓ), iridium oxide (IrOₓ) and platinum oxide (PtOₓ), rhodium oxide (RhOₓ), osmium oxide (OsOₓ) and palladium oxide (PdOₓ).

7. A ferroelectric memory device according to claim 1 wherein the buried contact is selected from the group consisting of tungsten, aluminum, copper and polysilicon doped or undoped with impurities.

8. A ferroelectric memory device according to claim 1 wherein the lower electrode comprises one of a plurality of lower electrodes, wherein the upper electrode overlaps at least two of the plurality of lower electrodes.

9. A ferroelectric memory device according to claim 8 further comprising:
an upper interlayer dielectric layer covering the ferroelectric layer and the upper electrode; and
a plate line electrically connected to the upper electrode through the upper interlayer dielectric layer.

10. A ferroelectric memory device according to claim 8 further comprising:
a strip line on the upper interlayer dielectric layer; and
an upper metal interlayer dielectric layer covering the strip line, wherein the plate line is electrically connected to the upper electrode through the upper metal interlayer dielectric layer and the upper interlayer dielectric layer.

11. A method of forming a ferroelectric memory device comprising:
forming an interlayer dielectric layer and a protection adhesion layer on a substrate respectively;
forming a contact hole through the interlayer dielectric layer and the protection adhesion layer to expose the substrate;
forming a buried contact in the contact hole that extends through the interlayer dielectric layer and the protection adhesion layer;
forming a lower electrode on the buried contact and on a portion of the protection adhesion layer adjacent to the buried contact to leave a remaining portion of the protection adhesion layer exposed;
forming a ferroelectric layer on the lower electrode and on the protection adhesion layer; and
forming an upper electrode on the ferroelectric layer and overlapping the lower electrode.

12. A method according to claim 11 wherein forming a buried contact comprises:
forming an upper buried contact portion comprising a barrier pattern extending from the lower electrode through the protection adhesion layer; and
forming a lower buried contact portion extending from the barrier pattern through the interlayer dielectric layer.

13. A method according to claim 11 wherein the protection adhesion layer comprises a titanium oxide layer.

14. A method according to claim 11 wherein forming a buried contact comprises:
forming a conductive layer on an entire surface of the substrate including in the contact hole to fill the contact hole with the conductive layer; and
planarizing the conductive layer to expose the protection adhesion layer and to form the buried contact in the contact hole.

15. A method according to claim 11, the method further comprising before forming the lower electrode:
recessing the buried contact to within the contact hole to form an upper portion of the buried contact beneath the protection adhesion layer;
forming a barrier layer in the contact hole on the upper portion of the buried contact to fill the contact hole; and
planarization the barrier layer to expose the protection adhesion layer and to form a barrier pattern on the upper portion of the buried contact.

16. A method according to claim 15 wherein the barrier pattern comprises a material selected from the group consisting of TiN, TiAlN, TiSiₓ, TiSiN, TaSiN and TaAlN.

17. A method according to claim 15 wherein forming a barrier layer comprises forming the barrier layer using at least one method selected from the group consisting of sputtering, chemical vapor deposition, sol-gel and atomic layer deposition.

18. A method according to claim 11 wherein the ferroelectric layer comprises a material selected from the group consisting of PZT[Pb(Zr, Ti)O₃], PbTiO₃, SrTiO₃, BaTiO₃, PbLaTiO₃, (Pb, La) (Zr, Ti)O₃, BST[(Ba, Sr)TiO₃], Ba₄Ti₃O₁₂, SrBi₂Ta₂O₉ and Bi₄Ti₃O₁₂.

19. A method according to claim 11 wherein the lower electrode and the upper electrode are formed of a material selected from the group consisting of ruthenium (Ru), iridium (Ir), platinum (Pt), rhodium (Rh), osmium (Os), palladium (Pd), iridium oxide (IrOₓ), and platinum oxide (PtOₓ), rhodium oxide (RhOₓ), osmium oxide (OsOₓ) and palladium oxide (PdOₓ).

20. A method according to claim 11 wherein forming a lower electrode comprises forming a plurality of lower electrodes, wherein forming an upper electrode comprises forming the upper electrode overlapping at least two of the plurality of lower electrodes.

21. A method according to claim 20 further comprising:
forming an upper interlayer dielectric layer covering the ferroelectric layer and the upper electrode; and
forming a plate line electrically connected to the upper electrode through the upper interlayer dielectric layer.

22. A method according to claim 21 further comprising before forming the plate line:
forming a strip line on the upper interlayer dielectric layer; and
forming an upper metal interlayer dielectric layer covering the strip line, wherein the plate line is electrically connected to the upper electrode through the upper metal interlayer dielectric layer and the upper interlayer dielectric layer.

23. A method according to claim 22 wherein the interlayer dielectric layer, the upper interlayer dielectric layer and the upper inter-metal dielectric layer are formed using a method selected from the group consisting of PECVD (Plasma-enhanced chemical vapor deposition), LPCVD (Low-pressure chemical vapor deposition), ALD (Atomic layer deposition) and SOG (Spin on glass).

24. A method according to claim 11 wherein the ferroelectric layer is formed using method selected from the group consisting of sputtering, CVD, sol-gel and atomic layer deposition.

25. A method according to claim 11 wherein the buried contact comprises a material selected from the group consisting of tungsten, aluminum, copper and polysilicon doped or undoped with impurities.
